(19) United States
(12) Patent Application Publication
(10) Pub. No.: US 2006/0060143 A1
(43) Pub. Date: Mar. 23, 2006

(54) Method and apparatus for forming a thin layer

(76) Inventors: Min-Woo Lee, Seoul (KR); Jin-Ho Jeon, Gyeonggi-do (KR); Kyoung-Sub Lee, Gyeonggi-do (KR); Young-Chol Kwon, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/233,614

(22) Filed: Sep. 23, 2005

(30) Foreign Application Priority Data
Sep. 23, 2004 (KR) 2004-76391

(51) Int. Cl. H01L 21/20; C23C 16/00

(52) U.S. Cl. 118/723 R; 118/715; 438/478

(57) ABSTRACT

In an apparatus and a method of uniformly forming a high quality thin layer, first and second gas lines are arranged on an inner surface of a processing chamber alternately with and spaced apart from each other by a same interval. The first and second gas lines have the same shape, and are positioned on a circumferential line farther than a peripheral portion of the substrate from the central axis of the substrate. An injection hole is formed on a shear plane of the gas lines. A first source gas, a reaction gas and a subsidiary gas area are supplied through the first gas line, and a second source gas is supplied through the second gas line. Accordingly, because of the spacing of the gas lines from the substrate, particles are prevented from being dropping onto the substrate and the apparatus may be repaired in a much shorter time, thereby remarkably improving maintenance efficiency of the apparatus.

### CROSS-REFERENCES TO RELATED APPLICATIONS

This application claims priority to Korean Patent Application No. 2004-76391 filed on Sep. 23, 2004, the content of which is herein incorporated by reference in its entirety.

### BACKGROUND OF THE INVENTION

1. Field of the Invention

The present invention relates to a method and an apparatus for forming a thin layer on a semiconductor substrate. More particularly, the present invention relates to a method and apparatus for forming a thin layer by using a source gas activated into plasma.

2. Description of the Prior Art

In semiconductor processing, the formation of high quality thin layers on semiconductor substrates is extremely important, especially with increases in device integration, performance, and die shrinkage.

In general, a thin layer is formed on a semiconductor substrate using either a physical vapor deposition (PVD) process or a chemical vapor deposition (CVD) process.

According to the PVD process, metal particles are separated from a target metal using an ionized gas, and are dropped onto a surface of a semiconductor substrate, thereby forming a metal thin layer on a semiconductor substrate. A known disadvantage to the PVD process for thin layer deposition, however, is that thickness uniformity of the deposited layer is relatively poor as compared with a CVD process. Accordingly, use of the PVD process is typically restricted to circumstances where thickness uniformity is not critical to operation of the semiconductor device formed using the process.

In contrast, a chemical reaction between source gases forms a thin layer on a surface of the substrate according to the CVD process. A typical thin layer by the CVD process includes an amorphous silicon layer, a silicon oxide layer, a silicon nitride layer and a silicon oxynitride layer.

The CVD process is classified into a low pressure CVD (LPCVD), an atmospheric pressure CVD (APCVD), a plasma enhanced CVD (PECVD) and a high pressure CVD (HPCVD) depending upon the internal pressure of a processing chamber applied during the CVD process. Among the above CVD processes, the PECVD process is widely used because it results in a high deposition rate at a lower temperature.

In the PECVD process, high energy electrons collide with neutral gas molecules, and each neutral gas molecule is decomposed into element atoms thereof. The decomposed atoms are deposited onto a surface of the substrate, thereby forming a thin layer on the substrate. One drawback of the PECVD process is that a slight deterioration of step coverage from the process causes voids in the thin layer deposited, and that these voids are exacerbated in thin layers deposited in subsequently steps. Voids formed in thin layers reduce the layer quality and causes various defects in subsequent processes.

An alternate to the PECVD process noted above is a high density plasma CVD (HDPCVD) process. The HDPCVD process simultaneously performs a thin film deposition step with an etching step using a sputtering process. The resulting thin layers may be coated on patterns without voids being formed in a gap between the patterns despite a high aspect ratio of the gap. The HDPCVD process, however, still results in some voids being formed in a thin layer. That is, when the gap is reduced between patterns or the thin layer is more complicated, a silicon oxide, which has been already etched by the sputtering process, is re-deposited onto patterns, so that a void is very possibly created in the thin layer due to an overhang structure. When the silicon oxide etched by the sputtering process is re-deposited onto the patterns, an overhang structure is formed at corner portions of the patterns, and the overhang may result a void during subsequent processes. Accordingly, as with PECVD, the HDPCVD process does completely eliminate unwanted voids formed in a thin layer.

Research is now being conducted to solve the problem of the above HDPCVD process. For example, an etching gas is supplemented into the source gas for the HDPCVD process, or a temperature of a substrate is controlled in accordance with processing conditions.

FIG. 1 is a cross sectional view illustrating a conventional high density plasma CVD apparatus, and FIG. 2 is a partially enlarged perspective view illustrating a gas supplier in FIG. 1.

Referring to FIGS. 1 and 2, a conventional HDPCVD apparatus includes a processing chamber 10, a chuck 20, a holder 30, first, second and third gas lines 42, 44 and 46, a cleaning gas line 50 and a high frequency wave generator 60.

A top portion of the processing chamber 10 is formed into a dome shape, and a coil of the high frequency wave generator 60 is positioned on an outer surface of the dome. A holder 30 is positioned on a bottom portion of the processing chamber 10, and the chuck 20 is secured to the holder 30. The cleaning gas line 50 is positioned at a lower portion of the processing chamber 10.

A plurality of the first, second and third gas line 42, 44 and 46 is installed on an inner side surface of the processing chamber 10. Particularly, six first gas lines 42, twelve second gas lines 44 and eighteen third gas lines 46 are installed on the inner side surface of the processing chamber 10. The first, second and third gas lines 42, 44 and 46 are spaced apart from each other along the inner side surface of the processing chamber 10 by a uniform distance and in symmetry with respect to a central line of the chuck 20. All of the first, second and third gas lines are directed over the chuck 20. The first gas line 42 has a length of about 20.5 cm (about 8.1 inch), the second gas line 44 has a length of about 4.5 cm (about 1.8 inch) and the third gas line 46 has a length of about 3.5 cm (about 1.4 inch). A silane (SiH₄) gas and a helium (He) gas are supplied into the processing chamber 10 through the first and third gas lines 42 and 46, and an oxygen (O₂) gas is supplied into the processing chamber 10 through the second gas line 44. A first injection hole 41 is formed on a side surface of the first gas line 42, and a second injection hole 43 is formed on a side surface of the second gas line 44. A third injection hole 45 is formed on a front surface of the third gas line 46.

When a substrate W is positioned on the chuck 20, a vacuum is created within the processing chamber 10. A first source gas and a reaction gas are then supplied into the processing chamber 10 through the first and third gas lines 42 and 46, and a second source gas is supplied into the processing chamber 10 through the second gas line 44. The reaction gas is activated into plasma by a high voltage applied thereto, and a chemical reaction between the first and second source gases is accelerated by the plasma, thereby forming a thin layer on the substrate W.

Though the resulting metal layers formed on substrate W are of generally high quality, unwanted deposition of the metal particles also occurs on the gas supply lines 42, 44 and 46. These lines must be cleaned or the deposited particles may become dislodged in subsequent processes and fall onto the substrate—particularly from line 42 which extends over a peripheral edge of substrate W—thereby forming defects in the surface of the substrate W. Maintenance of the device, as for cleaning, results in processing downtime since the device would necessarily need to be disassembled, cleaned, and then reassembled prior to use. Maintenance is further complicated by the fact that the first, second and third gas lines 42, 44 and 46 have their own length and position, so that the assembling of the disassembled apparatus is performed through innumerably repeated trial-and-error processes. In addition, when an orifice (not shown) is built in the injection holes 41, 43 and 45, the assembling of the apparatus takes a much longer time, and the process efficiency is remarkably reduced.

So as to solve the above problems, there has been suggested that the gas lines 42, 44 and 46 be shortened and specifications of the gas lines 42, 44 and 46 be standardized. However, the short length and standardization of the gas lines 42, 44 and 46 causes a non-uniform distribution of the source gas and the reaction gas within the chamber and around the wafer, thereby creating a defect in the thin layer formed on the substrate.

Accordingly, the need remains for an improved method of forming a high quality thin layer using an apparatus having a longer maintenance cycle.

### SUMMARY OF THE INVENTION

According to an exemplary embodiment of the present invention, there is provided a method of forming a thin layer on a semiconductor substrate. A processing gas and a subsidiary gas are supplied to a processing chamber along a circumferential line, each point of which is spaced apart by a same distance from a central axis of the substrate. The processing gas is activated into plasma, thereby forming the thin layer on the substrate, and the subsidiary gas accelerates a diffusion of the processing gas on a whole surface of the substrate.

According to an exemplary embodiment of the present invention, there is provided an apparatus for forming a thin layer on a semiconductor substrate, which comprises a processing chamber, a supporting member positioned in the chamber and a gas supplier through which gases are supplied into the processing chamber. The substrate is positioned on the supporting member, and a processing gas and a subsidiary gas are supplied into the processing chamber along a circumferential line, each point of which is spaced apart by a same distance from a central axis of the substrate. The processing gas is activated into plasma, thereby forming the thin layer on the substrate and the subsidiary gas accelerates a diffusion of the processing gas in the processing chamber. As an exemplary embodiment, the processing gas includes a first source gas, a second source gas and a reaction gas, and the gas supplier includes a first gas line through which the first source gas, the reaction gas and the subsidiary gas are supplied into the processing chamber and a second gas line through which the second source gas is supplied into the processing chamber. The first and second gas lines have the same shape, and are positioned on a circumferential line farther than a peripheral portion of the substrate from the central axis of the substrate. The first and second gas lines are arranged on an inner surface of the processing chamber alternately with each other and spaced apart from each other by a same interval. An injection hole is formed on a shear plane of the first and second gas lines.

According to the present invention, the processing gas and the subsidiary gas are supplied from a position spaced apart from a peripheral portion of the substrate, so that particles are prevented from being dropped onto the substrate, thereby forming a high quality thin layer on the substrate. Furthermore, the first and second gas lines are formed into the same shape and include an injection hole at a shear plane thereof. Thus, maintenance to the apparatus is performed in a much shorter time and in a much simpler way.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a cross sectional view illustrating a conventional high density plasma CVD apparatus;

FIG. 2 is a partially enlarged perspective view illustrating the gas supplier of FIG. 1;

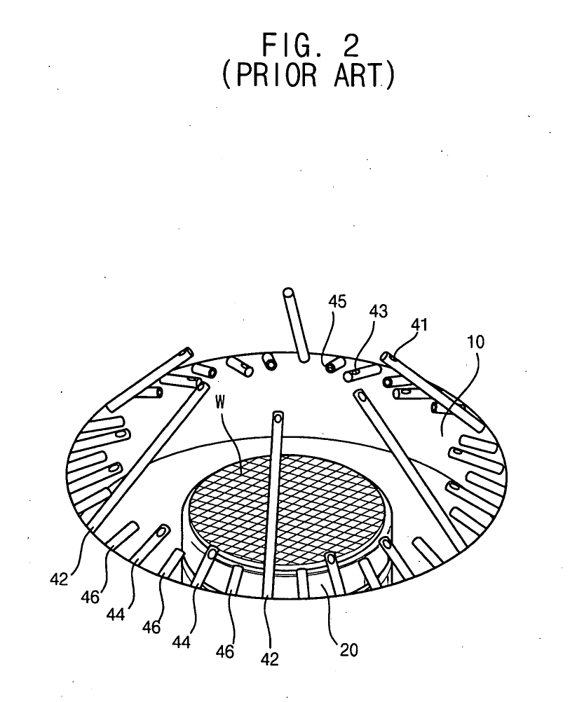

FIG. 3 is a cross sectional view illustrating an apparatus for forming a thin layer on a semiconductor substrate according to a first exemplary embodiment of the present invention;

FIG. 4 is a partially enlarged perspective view illustrating the gas supplier of the thin layer formation device of FIG. 3; and

FIG. 5 is a flow chart illustrating processing steps for a method of forming a thin layer on a semiconductor substrate according to a preferred embodiment of the invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

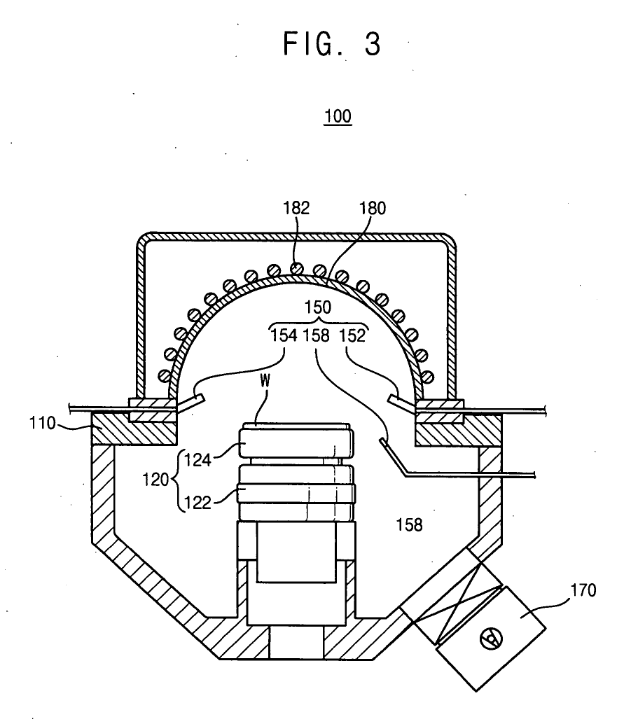

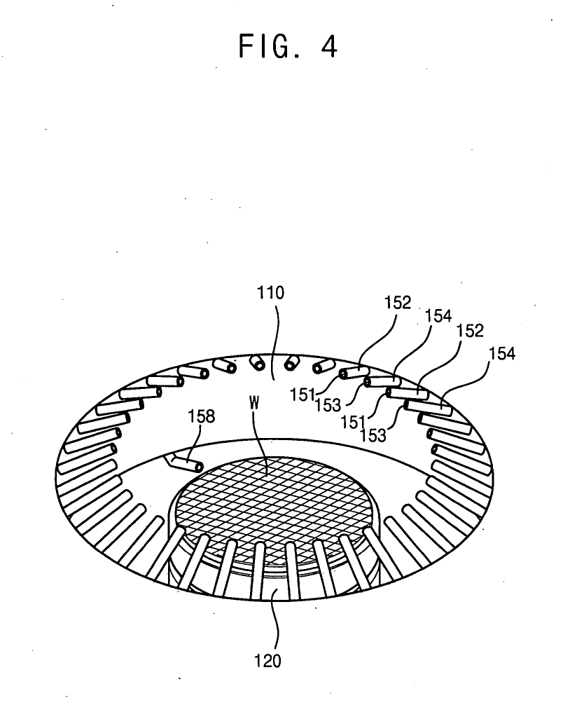

FIG. 3 is a cross sectional view illustrating an apparatus for forming a thin layer on a semiconductor substrate according to a first exemplary embodiment of the present invention, and FIG. 4 is a partially enlarged perspective view illustrating the gas supplier used in FIG. 3.

Referring to FIGS. 3 and 4, an apparatus 100 for forming a thin layer on a semiconductor substrate according to a first exemplary embodiment of the present invention includes a processing chamber 110, a supporting member 120 and a gas supplier 150.

A dome-shaped housing 180 is installed inside the processing chamber 110, and a coil 182 for generating a radio frequency (RF) wave (hereinafter referred to as RF coil) is positioned on an outer surface of the housing 180 for applying a radio frequency wave to an inside of the processing chamber 110. In the present embodiment, the RF coil 182 applies a high frequency wave of about 13.56 MHz to the inside of the processing chamber 110.

The supporting member 120 is positioned below the housing 180, and includes a holder 122 and an electrostatic chuck 124. The holder 122 is positioned at a lower portion of the processing chamber 110, and the electrostatic chuck 124 is positioned on the holder 122. In the present embodiment, a bias voltage is applied to the holder 122 at the same frequency as the RF wave generated through the RF coil.

A vacuum pump 170 is positioned at a side portion of the processing chamber 110 for setting an inside of the processing chamber 110 to a predetermined pressure. A capacity of the vacuum pump 170 may be varied in accordance with a specific process performed in the processing chamber 110, as would be known to one of the ordinary skill in the art.

The gas supplier 150 includes a first gas line 152, a second gas line 154 and cleaning gas line 158.

The first gas line 152 is substantially identical to the second gas line 154 in shape. A first injection hole 151 is formed on an end face of the first gas line 152, and a second injection hole 153 is formed on an end face of the second gas line 154. Positioning the injection holes 151 and 153 on the end faces of the gas lines 152 and 154 may shorten the time for maintenance of the apparatus 100, thereby improving an operation efficiency of the apparatus 100.

A specification and a shape of the first and second injection holes 151 and 153 may be varied in accordance with an injection rate of the gas penetrating the holes 151 and 153. That is, the first and second gas lines 152 and 154 may have different flow rates from each other. As an exemplary embodiment, an orifice (not shown) may be positioned in the first and second injection holes 151 and 153 for controlling the injection rate of the injection holes 151 and 153.

The first and second gas lines 152 and 154 have a length of about 2 cm to 10 cm, and preferably, a length of about 3 cm to 5 cm. In the present embodiment, the first and second gas lines 152 and 154 have a length of about 3.5 cm. Although the first and second gas lines 152 and 154 have been described to have the above length, it is understood that the first and second gas lines 152 and 154 should not be limited to those exemplary lengths, but various changes can be made in their length by one skilled in the art. Particularly, a length of the first and second gas lines 152 and 154 may be varied without limitations supposing that the first and second injection holes are not positioned on a peripheral portion of the substrate W. That is, the first and second gas lines may be elongated under the condition that a vertical line that is parallel with the central axis line of the substrate and makes contact with the gas lines does not meet the peripheral portion of the substrate. The first and second gas lines are positioned spaced apart from the peripheral portion of the substrate W, so that impurities at the end portion of the gas lines 152 and 154 are prevented from being dropped onto the substrate W.

The first and second gas lines 152 and 154 are positioned at the same horizontal surface along an inner surface of the processing chamber 110. In the present embodiment, eighteen first gas lines 152 and eighteen second gas lines 154 are alternately arranged with each other at a uniform interval inside the processing chamber 110.

The first and second gas lines 152 and 154 extend from the inner surface of the processing chamber 110 towards a space over the substrate W at a predetermined angle with respect to a top surface of the substrate W. In the present embodiment, the first and second gas lines are inclined upwards at an angle of about 45°. The incline angle or a gradient of the first and second gas lines may be varied in accordance with processing conditions, as would be known to one of the ordinary skill in the art.

A processing gas is supplied into the processing chamber 110 through the gas supplier 150. The processing gas includes a first source gas, a second source gas and a reaction gas, and is varied in accordance with a thin layer that is to be formed on the substrate W.

The first source gas, the reaction gas and a subsidiary gas are supplied to the processing chamber 110 through the first gas line 152. The first source gas is selected in accordance with a kind of the thin layer on the substrate W. For example, when a silicon oxide (SiO₂) layer is to be formed on the substrate W, a silicon source gas is selected as the first source gas, and when a nitride layer is to be formed on the substrate W, a nitrogen source gas is selected as the first source gas.

The reaction gas includes an inactive gas, for example, an inert gas such as helium (He) gas and argon (Ar) gas, and activates the first and second source gases into plasma, thereby generating ions and radicals. The radicals are deposited onto a surface of the substrate W, and are chemically and physically reacted with atoms on a surface of the substrate W, thereby forming the thin layer on the substrate W.

The subsidiary gas accelerates a diffusion of the first source gas in the processing chamber 110. The first gas lines 152 have a short and substantially identical length relatively as compared with a conventional gas line; thus, the first source gas may be non-uniformly distributed on a surface of the substrate W. The subsidiary gas compensates for the non-uniform distribution of the first source gas in the processing chamber 110. The subsidiary gas exemplarily includes a material having a small molecular weight such as hydrogen (H₂) gas.

In the present embodiment, silane (SiH₄) gas is used as the first source gas, helium (He) gas is used as the reaction gas, and the hydrogen (H₂) gas is used as the subsidiary gas. However, the first source gas, the reaction gas and the subsidiary gas may be varied in accordance with a thin layer that is to be formed, as would be known to one of the ordinary skill in the art.

The second source gas is supplied into the processing chamber 110 through the second gas lines 154, and is selected in accordance with the first source gas and the thin layer that is to be formed. For example, when an oxide layer is to be formed on the substrate W, an oxygen (O₂) source gas is selected as the second source gas, and when a nitride layer is to be formed on the substrate W, a nitrogen trifluoride (NF₃) gas is selected as the second source gas.

The second source gas may further include an additional gas for removing impurities or particles. An example of the additional gas includes a gas including fluorine (F). In case the second source gas includes fluorine (F₂) gas, the subsidiary gas including hydrogen (H₂) gas functions as a blocking gas for preventing damage to a thin layer due to the fluorine (F₂) gas.

The cleaning gas line 158 is installed at an inner side surface of the processing chamber 110 adjacent to the vacuum pump 170, and is positioned below the first and second gas lines 152 and 154. An injection hole of the cleaning gas line 158 is directed toward the housing 180 of the processing chamber 110.

A cleaning gas is supplied into the processing chamber 110 through the cleaning gas line 158. An example of the cleaning gas includes a perfluoro compound (PFC)-based gas. A purge gas may also be supplied into the processing chamber through the cleaning gas line 158.

Experiment 1

A silicon oxide layer was formed on each of 25 semiconductor substrates to a target thickness of about 6500 Å in the apparatus disclosed in Embodiment 1. A silane gas was supplied to the processing chamber at a flow rate of 80 standard cubic centimeters per minute (sccm) as the first source gas, an oxygen (O₂) gas was supplied at a flow rate of about 160 sccm as the second source gas, a helium (He) gas was supplied at a flow rate of about 200 sccm as the reaction gas and a hydrogen (H₂) gas was supplied at a flow rate of about 400 sccm as the subsidiary gas. In the present embodiment, the first and second source gases, the reaction gas and the subsidiary gas was supplied to the processing chamber 110 for about 164 seconds. An electric power of about 6000 W to about 6500 W was applied to the processing chamber 110. A high frequency alternating voltage was used as the electric power. A thickness of the silicon oxide layer on each of the substrates was measured and listed on the following Table 1.

TABLE 1
Experiment 1 Results

| Substrate | Thickness | Thickness | Thickness | Thickness | |
|---|---|---|---|---|---|
| No. | Avg. (Å) | Min. (Å) | Max. (Å) | Difference | |
| 1 | 6488 | 6271 | 6649 | 378 | |
| 2 | 6550 | 6354 | 6713 | 359 | |
| 3 | | | | | Failure |
| 4 | 6584 | 6370 | 6747 | 377 | |
| 5 | 6579 | 6377 | 6759 | 382 | |
| 6 | 6574 | 6372 | 6750 | 378 | |
| 7 | 6581 | 6381 | 6761 | 379 | |
| 8 | 6583 | 6382 | 6759 | 377 | |
| 9 | 6578 | 6375 | 6757 | 382 | |
| 10 | 6586 | 6383 | 6760 | 377 | |
| 11 | 6586 | 6379 | 6763 | 384 | |
| 12 | 6587 | 6384 | 6758 | 374 | |
| 13 | 6587 | 6383 | 6758 | 375 | |
| 14 | 6495 | 6164 | 6696 | 531 | |
| 15 | 6552 | 6260 | 6747 | 487 | |
| 16 | | | | | Failure |
| 17 | 6580 | 6307 | 6768 | 461 | |
| 18 | 6581 | 6315 | 6784 | 468 | |
| 19 | 6576 | 6315 | 6784 | 469 | |
| 20 | 6583 | 6326 | 6782 | 455 | |
| 21 | | | | | Failure |
| 22 | 6584 | 6345 | 6771 | 426 | |
| 23 | 6587 | 6343 | 6778 | 435 | |
| 24 | 6661 | 6312 | 6839 | 427 | |
| 25 | | | | | Failure |

The above experimental results show that an average thickness of the silicon oxide layer of each substrate ranges from a minimum thickness of about 6488 Å to a maximum thickness of about 6661 Å, for a difference between minimum average and maximum average of about 173 Å, or about 2.6% variance. Furthermore, the above experimental results also show that a thickness difference of the silicon oxide layer of each substrate ranges from a minimum difference of about 359 Å to a maximum difference of about 531 Å. The thickness difference range is sufficiently acceptable in view of an allowable thickness difference of about 700 Å.

The above experimental results indicate that a thin layer may be formed on a semiconductor substrate using methods taught in the present invention that result in a processing error that is much lower than one that is conventionally allowable.

Experiment 2

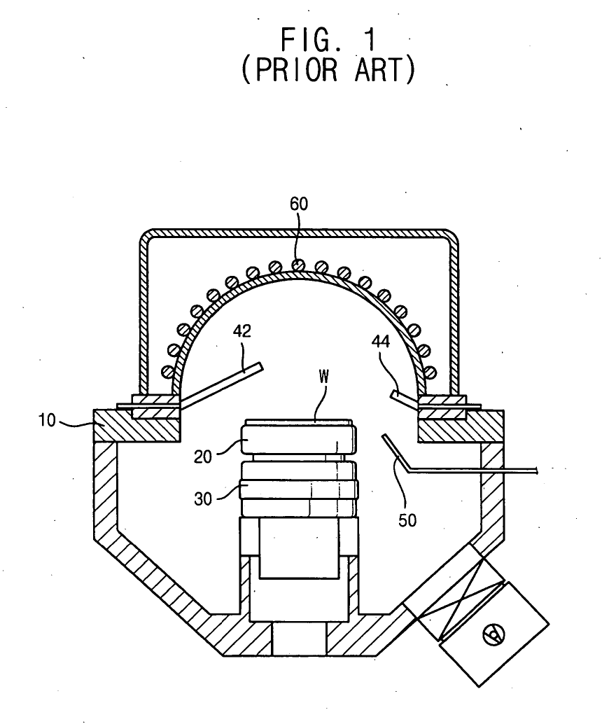

A silicon oxide layer was formed on a first semiconductor substrate to a target thickness of about 1900 Å in a conventional apparatus shown in FIG. 1, and a silicon oxide layer was formed on each of 5 semiconductor substrates, a second through a sixth substrate to a thickness of about 1900 Å. A silane gas was supplied to the processing chamber at a flow rate of 80 standard cubic centimeters per minute (sccm) as the first source gas, an oxygen (O₂) gas was supplied at a flow rate of about 160 sccm as the second source gas, a helium (He) gas was supplied at a flow rate of about 200 sccm as the reaction gas and a hydrogen (H₂) gas was supplied at a flow rate of about 400 sccm as the subsidiary gas. In the present embodiment, the first and second source gases, the reaction gas and the subsidiary gas was supplied to the processing chamber 110 for about 164 seconds. An electric power of about 6000 W to about 6500 W was applied to the processing chamber 110. A high frequency alternating voltage was used as the electric power. A thickness of the silicon oxide layer on each of the substrates was measured and listed on the following table 2. In the present experiment, the thickness of the silicon oxide layer was measured at thirteen points of each substrate.

TABLE 2
Experiment 2 Results

| | Conventional | | | | | |
|---|---|---|---|---|---|---|
| Substrate | Apparatus | Apparatus According to Embodiment 1 | | | | |
| Point | 1 | 2 | 3 | 4 | 5 | 6 |
| 1 | 2167 | 2045 | 2050 | 2080 | 2088 | 2055 |
| 2 | 2107 | 2030 | 2031 | 2060 | 2069 | 2037 |
| 3 | 2107 | 1992 | 1997 | 2017 | 2027 | 2004 |
| 4 | 2124 | 2071 | 2077 | 2074 | 2084 | 2084 |
| 5 | 2100 | 2053 | 2057 | 2026 | 2035 | 2063 |
| 6 | 2050 | 2062 | 2063 | 2036 | 2042 | 2066 |
| 7 | 1957 | 2026 | 2027 | 2069 | 2076 | 2030 |
| 8 | 1942 | 2068 | 2073 | 2066 | 2073 | 2076 |
| 9 | 2124 | 2077 | 2081 | 2065 | 2074 | 2085 |
| 10 | 2044 | 2037 | 2039 | 2032 | 2037 | 2041 |
| 11 | 2024 | 2020 | 2020 | 2030 | 2036 | 2020 |
| 12 | 2105 | 2040 | 2044 | 2056 | 2062 | 2046 |
| 13 | 1934 | 2042 | 2044 | 2035 | 2042 | 2045 |
| Thickness | 2061 | 2043 | 2046 | 2050 | 2057 | 2050 |
| Avg. | | | | | | |
| Thickness | 233 | 85 | 83 | 63 | 61 | 80 |
| Diff. | | | | | | |

As shown in Table 2, an average thickness of the silicon oxide layer on the first substrate is about 2061 Å, and a maximum thickness difference is about 233 Å. However, an average thickness of the silicon oxide layer on each of the second through sixth substrates ranges from a minimum thickness of about 2043 Å to a maximum thickness of about 2057 Å, and a thickness difference ranges from a minimum difference of about 61 Å to a maximum difference of about 84 Å. That is, the above experimental results confirm that the device of the present invention can form a thin layer to a thickness more closely to the target thickness than by using a conventional apparatus. The experimental results also confirm that a thin layer is formed more uniformly in the apparatus in Embodiment 1 than in a conventional apparatus.

### Embodiment 2

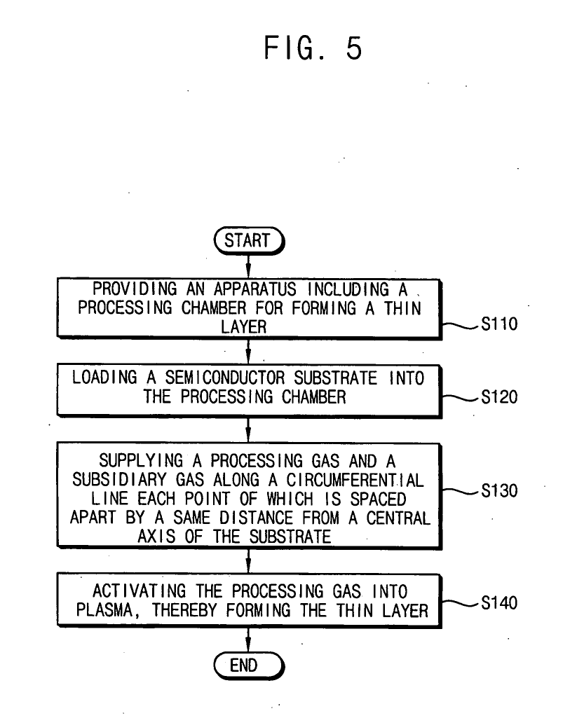

FIG. 5 is a flow chart illustrating processing steps for a method of forming a thin layer on a semiconductor substrate. An apparatus for forming a thin layer, such as that shown in FIG. 3, is first provided (step S110). The thin layer is to be formed on a semiconductor substrate in a processing chamber of the apparatus using a chemical reaction accelerated by plasma. A power source is installed to the apparatus, and a high frequency voltage is applied to the processing chamber.

The semiconductor substrate is loaded into the processing chamber (step S120), and a processing gas and a subsidiary gas are supplied into the processing chamber along a circumferential line, each point of which is spaced apart by the same distance from a central axis of the substrate (step S130). The processing gas includes a first source gas, a second source gas and a reaction gas.

In the present embodiment, the circumferential line is farther than a peripheral portion of the substrate from the axis of the substrate, so that a circle formed by the circumferential line has a size larger than that of the substrate, and the processing gas and the subsidiary gas are supplied to the processing chamber from a position spaced apart from a peripheral portion of the substrate.

The first and second source gases are selected in accordance with a thin layer that is to be formed on the substrate. For example, when a silicon oxide (SiO₂) layer is formed on the substrate, a silicon-based gas is selected as the first source gas and an oxygen-based gas is selected as the second source gas.

The reaction gas activates the first and second source gases into plasma, thereby generating a plurality of ions and radicals. An example of the reaction gas includes an inactive gas such as an inert gas, e.g. helium (He) or argon (Ar).

The subsidiary gas accelerates a diffusion of the first and second source gases, so that the first and second source gases are uniformly distributed within the processing chamber, thereby improving deposition uniformity on the substrate. An example of the subsidiary gas includes a gas having a small molecular weight such as hydrogen (H₂) gas.

As an exemplary embodiment, the subsidiary gas is supplied to the processing chamber simultaneously with the first or second source gas. For example, the first source gas, the reaction gas and the subsidiary gas may be supplied through the first gas line, and the second source gas may be supplied through the second gas line. For another example, the first source gas and the reaction gas are supplied through the first gas line, and the second source gas and the subsidiary gas are supplied through the second gas line. For still anther example, the first source gas, the reaction gas and the subsidiary gas are supplied through the first gas line, and the second source gas and the subsidiary gas are supplied through the second gas line.

In the present embodiment, the first and second gas lines have the same shape, so that the processing gas and the subsidiary gas are supplied to the processing chamber through the same gas lines. The above standardization of the gas lines facilitates an assembly of the apparatus after performing a periodic maintenance to the apparatus. In addition, an injection hole is formed on a shear plane of the gas line, so that the inside bore of the gas lines may be easily cleansed during maintenance of the apparatus.

The processing gases are too numerous to restrict to some kinds of gases, and most technical information on the gases have been known to those of an ordinary skill in the art. Accordingly, the processing gas and the subsidiary gas are selected among the present various gases in accordance with a thin layer that is to be formed on the substrate.

Then, a high frequency voltage is applied to the processing chamber, and the first and second source gases and the reaction gas are activated into plasma (step S140). In the present embodiment, an alternating voltage having a frequency is about 13.56 MHz is applied to the processing chamber. A bias voltage having a frequency is about 13.56 MHz may also be further applied to the substrate. Accordingly, a thin layer is coated on the substrate by a chemical reaction between the processing gases in the processing chamber under plasma.

In the present embodiment, the first and second source gases, the reaction gas and the subsidiary gas are supplied at positions spaced apart from the peripheral portion of the substrate along a circumferential line sized larger than that of the substrate. In this way, an impurity drop from the gas lines to the substrate is sufficiently prevented due to an interval between the substrate and the gas lines. In addition, the subsidiary gas accelerates a diffusion of the processing gas in the processing chamber so that the processing gas is uniformly distributed in the processing chamber even though the processing gas is injected at the same circumferential line. As a result, a thin layer is formed on the substrate with a higher quality in a shorter time.

According to the present invention, a specification of the gas lines through which the processing gas is supplied into the processing chamber is standardized, and an injection hole is formed on a shear plane of the gas lines. As a result, particles are prevented from being dropping onto the substrate, and the apparatus may be repaired in a much shorter time, thereby remarkably improving maintenance efficiency of the apparatus. Particularly, an assembly of the apparatus after performing the maintenance to the apparatus takes a much shorter time and the maintenance cycle becomes very much elongated due to the standardization of the gas lines. In addition, a distribution uniformity of the processing gas is not deteriorated despite the use of uniformly sized gas lines due to concurrent use of a subsidiary gas with the source gas(s), so that the thin layer is uniformly formed on the substrate with a high quality.

Although the exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A method of forming a thin layer on a semiconductor substrate, comprising:
supplying a processing gas and a subsidiary gas into a chamber in which a semiconductor substrate is mounted, said gases being supplied entirely along a circumferential line disposed about a central axis of the semiconductor substrate, said subsidiary gas adapted to help diffuse the processing gas over a whole surface of the substrate; and
activating the processing gas into plasma to form a thin layer on the substrate.

2. The method of claim 1, the substrate having a peripheral edge, and wherein the circumferential line is outside of the substrate peripheral edge so that the processing gas and the subsidiary gas are supplied into the chamber from a position spaced apart from the peripheral edge of the substrate.

3. The method of claim 1, wherein the subsidiary gas includes hydrogen (H₂) gas.

4. The method of claim 1, wherein the processing gas includes first and second source gases for forming the thin layer and a reaction gas for activating the first and second source gases into plasma.

5. The method of claim 4, wherein the first source gas includes one selected from the group consisting of silicon gas and nitrogen gas.

6. The method of claim 4, wherein the second source gas includes oxygen gas.

7. The method of claim 4, wherein the reaction gas includes an inactive gas.

8. The method of claim 4, further including supplying the first source gas, the reaction gas and the subsidiary gas into the chamber through a common gas line.

9. The method of claim 4, further including supplying the first source gas and reaction gas through a first common gas line, and second source gas and subsidiary gas into the chamber through a second common gas line.

10. The method of claim 4, further including supplying the first source gas, the reaction gas and the subsidiary gas into the chamber through a first common gas line, and second source gas and subsidiary gas through a second common gas line.

11. The method of claim 1, wherein the thin layer includes one of an oxide layer and a nitride layer.

12. An apparatus for forming a thin layer on a semiconductor substrate, comprising:
a processing chamber;
a supporting member positioned in the chamber and adapted to support the semiconductor substrate at a mounting position thereon;
a gas supplier having a plurality of gas injection holes arranged about a circumferential line within the chamber for supplying a processing gas and a subsidiary gas into the processing chamber, each point of the circumferential line being spaced apart from the mounting position of the substrate by an identical distance; and
a plasma activator for activating the processing gas to plasma and forming a thin layer on the substrate, with the subsidiary gas accelerating a diffusion of the processing gas within the processing chamber.

13. The apparatus of claim 12, wherein the circumferential line of gas injection holes is formed at a location within the chamber that is outside of a peripheral portion of the substrate when the substrate is mounted at the mounting position on the supporting member.

14. The apparatus of claim 12, wherein the gas supplier includes a plurality of first gas lines and a plurality of second gas lines having the injection holes formed on end faces thereof, and the processing gas includes a first source gas, a second source gas and a reaction gas.

15. The apparatus of claim 14, wherein the first source gas, the reaction gas and the subsidiary gas are supplied into the processing chamber through the first gas lines, and the second source gas is supplied into the processing chamber through the second gas lines.

16. The apparatus of claim 14, wherein the first source gas and reaction gas are supplied into the processing chamber through the first gas lines, and the second source gas and subsidiary gas are supplied into the processing chamber through the second gas lines.

17. The apparatus of claim 14, wherein the first source gas, the reaction gas and the subsidiary gas are supplied into the processing chamber through the first gas lines, and the second source gas and subsidiary gas are supplied into the processing chamber through the second gas lines.

18. The apparatus of claim 14, wherein the first and second gas lines are disposed at a predetermined angle with respect to a top surface of the supporting member on which the semiconductor substrate is mounted.

19. The apparatus of claim 18, wherein the predetermined angle is about 45° inclined upward relative to the top surface of the supporting member.

20. The apparatus of claim 14, wherein the first and second gas lines are arranged on an inner surface of the processing chamber alternately with each other and spaced apart from each other by a same interval.

21. The apparatus of claim 14, wherein the first and second gas lines have a length of about 2 cm to 10 cm.

22. The apparatus of claim 21, wherein the first and second gas lines have a length of about 3 cm to 5 cm.

23. The apparatus of claim 22, wherein the first and second gas lines have a length of about 3.5 cm.

24. The apparatus of claim 12, further comprising a cleaning gas line through which a cleaning gas is supplied into the processing chamber.
